(19) United States
(12) Patent Application Publication
(10) Pub. No.: US 2026/0038586 A1
(43) Pub. Date: Feb. 5, 2026

(54) RANDOM ACCESS MEMORY USING FLEXIBLE BIT TRUNCATION

(71) Applicant: University of South Alabama, Mobile, AL (US)

(72) Inventors: Na Gong, Mobile, AL (US); William Donald Oswald, Mobile, AL (US); Jinhui Wang, Mobile, AL (US)

(73) Assignee: University of South Alabama, Mobile, AL (US)

(21) Appl. No.: 19/287,955

(22) Filed: Aug. 1, 2025

Related U.S. Application Data
(60) Provisional application No. 63/678,604, filed on Aug. 2, 2024.
(60) Provisional application No. 63/685,646, filed on Aug. 21, 2024.

(51) Int. Cl. G11C 11/418; G11C 5/06; G11C 5/14; G11C 11/419

(52) U.S. Cl. CPC G11C 11/418; G11C 5/063; G11C 5/147; G11C 11/419

(57) ABSTRACT

A plurality of random access memory (RAM) cells is accessed. The RAM cells are arranged in an array and include bitlines and wordlines. The bitlines and wordlines are functionally accessible for data storage and retrieval. The accessibility is based on logic circuitry coupled to the array and to power inputs, address inputs, control inputs, and data inputs and outputs. A truncation manager is coupled to the array for controlling the bitlines. The truncation manager selectively controls bitline power and bitline data output. Bitline power header devices are coupled to the array. The bitline power header devices selectively distribute power along each of the bitlines. Bitline output multiplexors are coupled to the array. The bitline output multiplexors selectively couple the bitlines to the data outputs. The truncation manager controls a plurality of truncation logic units.

### RELATED APPLICATIONS

This application claims the benefit of U.S. provisional patent application “Random Access Memory Using Flexible Bit Truncation” Ser. No. 63/678,604, filed Aug. 2, 2024, and “Machine Learning Processing Using Flexible Bit Truncation” Ser. No. 63/685,646, filed Aug. 21, 2024.

Each of the foregoing applications is hereby incorporated by reference in its entirety.

### STATEMENT REGARDING FEDERALLY SPONSORED RESEARCH OR DEVELOPMENT

This invention was made with government support under OIA2218046 awarded by the National Science Foundation. The government has certain rights in the invention.

### FIELD OF ART

This application relates generally to data manipulation and more particularly to random access memory using flexible bit truncation.

### BACKGROUND

Data is the currency of nearly all organizations today. Data is collected from individuals, groups, devices, web-connected devices, and ecommerce websites, among other sources. The collected data can be sold legitimately or for nefarious purposes and is streamed to provide information. The data can be acquired passively as a user surfs the Internet or can be provided willingly by a user. Such data collection ranges from monitoring websites visited, menus selected, and buttons clicked, to actively requesting personal information and login credentials. The collected data can be analyzed for research, or can be scrutinized to develop investment strategies, to plan renewable energy sources, or to predict the hottest new “must-have” item. The streamed data can provide news and information, sporting events, television programs and movies, and silly pet videos. However, some of the data that is sold or streamed can be misleading, particularly when the data has been tampered with or intentionally corrupted. “Deep fake” photos, videos, and audio streams are circulated with the intent of deception, misinformation, and criminal activities.

Electronic devices such as personal electronic devices have become immensely popular. The most favored personal electronic device, the cellular telephone, and in particular the smartphone, now enables individuals nearly anywhere in the world to communicate using voice, text, and email. These devices are also useful for ecommerce because they enable ordering and paying for goods and services online. The devices further support financial services such as online banking, stock trading, and currency exchange. The phones also support information consumption such as obtaining news, weather, and sports information including World Cup scores or Olympic medal counts among many others. The phones also provide access to maps, jungle gym plans, ride sharing, and short-term house rentals.

The success of the personal electronic devices is supported by the devices being internet-connected. Other internet-connected electronic devices monitor buildings, provide fire protection, and even let someone know when the milk has spoiled. These latter devices, often referred to as the Internet of Things (IoT), include smart thermostats; fire, smoke, and carbon monoxide detectors; and appliances. These devices support households and organizations by monitoring energy usage, supply levels, and safety. The data collected from the personal electronic and IoT devices greatly expands the types of data that are collected, and the services that can be provided based on the data. Further data can be collected from a more diverse group of individuals. The diversity of the individuals, and the diversity of the data they provide, greatly enhances research and analysis tasks. The data analysis is able to better understand gender, cultural, and geographical preferences for goods and services, information sources, purchasing, and media sources. This diverse information further enables analysis of energy efficiency and usage, incidence and spread of disease, and damage associated with naturally occurring events including storms and political events such as war. However, all of this data needs to be stored and processed in order to be useful.

### SUMMARY

Data streaming services have proliferated as users of devices such as personal electronic devices have migrated away from traditional information sources such as newspapers, radio, and television. Instead, these users now receive their daily news, sports scores, television programs, and movies on their devices. Popular streaming services provide a wide variety of programming content ranging from that which is suitable for preschoolers to “mature” content. While some streaming services provide “free” content, typically with intrusive advertising, users can view premium “ad-free” streams by subscribing to one or more streaming services. Users can catch up the latest law enforcement series from New Zealand as easily as viewing American sitcom reruns. From the user's point of view, the streaming services provide viewing opportunities on electronic devices in use at virtually any location on Earth. From the stream providers' point of view, providing the video streams is a highly complex problem that is complicated by technical challenges including network bandwidth, numbers of users accessing a video stream, and even the intensity of ambient light at the user's location. These technical challenges can be overcome by limiting the amount of data that is transferred from a streaming service provider's server to the user's client device. The streaming data that is transferred can be truncated in order to reduce the amount of data that is provided to the data stream.

Techniques for data manipulation based on a random access memory using flexible bit truncation are disclosed. A plurality of random access memory (RAM) cells is accessed. The RAM cells can include read-write cells such as static RAM (SRAM) cells. The RAM cells are arranged in an array. The array can include one or more SRAM cell topologies such as a six-transistor circuit topology. The array cells comprise bitlines and wordlines. The wordlines are used to select words within the array, where a word can include a plurality of RAM cells such as 16 cells, 32 cells, and so on. The bitlines are used to load and store data. The bitlines and wordlines are functionally accessible for data storage and retrieval. The functional accessibility is based on logic circuitry coupled to power inputs, address inputs, control inputs, and data inputs and outputs. The logic circuitry is further coupled to the array. A truncation manager is coupled to the RAM array for controlling the bitlines within the array. One or more bitlines can be truncated when loading data in order to reduce power consumption by the RAM array. The truncation is accomplished without degrading the quality of the data. The truncation manager selectively controls bitline power and bitline data output. Bitline power header devices are coupled to the RAM array. The bitline power header devices can include a power header device pair, where the pair includes a p-type device and an n-type device. The p-type power header device of the power header device pair controls source current power distribution for the bitline. The n-type power header device of the power header device pair controls sink current power distribution for the bitline. The bitline power header devices selectively distribute power along each of the bitlines. Bitline output multiplexors are coupled to the RAM array. The bitline output multiplexors selectively couple the bitlines to the data outputs.

An apparatus for data manipulation is disclosed comprising: a plurality of random access memory (RAM) cells arranged in an array, wherein the array cells comprise bitlines and wordlines, wherein the bitlines and wordlines are functionally accessible for data storage and retrieval, wherein the functional accessibility is based on logic circuitry coupled to power inputs, address inputs, control inputs, and data inputs and outputs, and wherein the logic circuitry is further coupled to the array; a truncation manager for controlling the bitlines within the array, wherein the truncation manager selectively controls bitline power and bitline data output; bitline power header devices, wherein the bitline power header devices selectively distribute power along each of the bitlines; and bitline output multiplexors, wherein the bitline output multiplexors selectively couple the bitlines to the data outputs. In embodiments, the truncation manager controls a plurality of truncation logic units. In embodiments, each truncation logic unit of the plurality of truncation logic units controls a bitline. In embodiments, the truncation manager is controlled by one or more of the address inputs, the control inputs, and the data inputs and/or outputs. In embodiments, the controlling the truncation manager enables a variable number of bitlines to be deselected. In embodiments, the controlling the truncation manager further enables the deselected bitlines to be powered off using the bitline power header devices.

Various features, aspects, and advantages of various embodiments will become more apparent from the following further description.

### BRIEF DESCRIPTION OF THE DRAWINGS

The following detailed description of certain embodiments may be understood by reference to the following figures wherein:

FIG. 1 is a flow diagram for a random access memory using flexible bit truncation.

FIG. 2 is a flow diagram for truncation manager usage.

FIG. 3 illustrates a memory structure.

FIG. 4 is a system block diagram showing truncation management and power gating.

FIG. 5 shows truncation manager circuitry and a truth table.

FIG. 6 illustrates a six-transistor bit cell with power gates.

FIG. 7 is a system diagram for a random access memory using flexible bit truncation.

### DETAILED DESCRIPTION

Techniques for data manipulation based on a random access memory using flexible bit truncation are disclosed. The techniques can be used for various applications, such as machine learning, video steaming, image processing, and so on. The data processing technique of using machine learning to manipulate data has become extremely popular recently. Artificial intelligence (AI) functions are widely available through various interfaces and applications. Unfortunately, machine learning/AI can require and consume incredible amounts of energy to achieve its processing goals. Disclosed techniques can greatly reduce data storage power requirements while maintaining a necessary level of computational accuracy by flexibly controlling which storage bits in an array can be “turned off” to save power. This allows an AI application that requires full 32-bit precision, for example, to run on the same hardware that will subsequently support an application that may only require 12-bits of precision. Thus, power is saved in a flexible manner, according to the computational needs of the running application, sub-application, network layer, inference engine, etc.

Random access memory using flexible bit truncation enables data manipulation. The data manipulation can include reducing the amount of data that is provided to a user. The data can be provided as a stream such as a video stream. The data reduction can be accomplished using truncation of the data. The truncating includes “removing” one or more least significant bits (LSBs) of each data word while the data word is accessed in a random access memory (RAM). In embodiments, an “optimal” value for the removed LSBs can be assigned. The number of LSBs to be truncated can be based on an application such as a video application or a machine learning application. The reduced data provides a stream of sufficient quality to maintain a user experience (UX) level.

A plurality of random access memory (RAM) cells is accessed. The RAM cells can include random access read-write cells such as static RAM (SRAM) cells. The RAM cells are arranged in an array. The array can include one or more SRAM cell topologies such as a six-transistor circuit topology. The array cells include bitlines and wordlines. The wordlines are used to select words within the array, where a word can include a plurality of RAM cells such as 16 RAM cells, 32 RAM cells, and so on. The bitlines are used to load and store data. The bitlines and wordlines are functionally accessible for data storage and retrieval. The functional accessibility is based on logic circuitry coupled to power inputs, address inputs, control inputs, and data inputs and outputs. The logic circuitry is further coupled to the array to control and operate the array. A truncation manager is coupled to the RAM array for controlling the bitlines within the array. One or more bitlines can be truncated when loading data in order to reduce power consumption by the RAM array. The truncation is accomplished without degrading the quality of the data. The truncation manager selectively controls bitline power and bitline data output. Bitline power header devices are coupled to the RAM array. The bitline power header devices can include a power header device pair, where the pair includes a p-type device and an n-type device. The p-type power header device of the power header device pair controls source current power distribution for the bitline. The n-type power header device of the power header device pair controls sink current power distribution for the bitline. The bitline power header devices selectively distribute power along each of the bitlines. Bitline output multiplexors are coupled to the RAM array. The bitline output multiplexors selectively couple the bitlines to the data outputs.

In addition, in order to determine how many bits may be truncated without losing accuracy for a given machine learning algorithm or program, techniques for machine learning processing using flexible bit truncation are disclosed. A machine learning network is accessed. The ML network can include one or more layers, where the layers can include an input layer, an output layer, an intermediate or hidden layer, and so on. A layer of the ML network can include a convolutional layer. At least one of the processing layers is sourced with flexible bit truncation storage hardware. The flexible bit truncation storage hardware truncates the storage contents before sourcing them to a layer. A flexible bit truncation setting is determined for the at least one of the one or more processing layers. The determining the truncation setting can be based on analyzing the number of bits that can be truncated while maintaining processing accuracy by the ML network. Further, the determining is based on an application to be executed on the machine learning network. The determining can be based on a number of bits associated with data elements to be processed by the ML network. The flexible bit truncation setting is programmed in the flexible bit truncation storage hardware of the at least one of the one or more processing layers. The flexible bit truncation setting occurs in real time during application runtime. Further, the programming the flexible bit truncation setting changes dynamically during runtime. The application is executed using the flexible bit truncation setting. The execution can include generating a classification, converging on an inference, and so on.

A method for machine learning processing comprises accessing a machine learning network, wherein the machine learning network includes one or more processing layers, and wherein at least one of the one or more processing layers is sourced with flexible bit truncation storage hardware; determining a flexible bit truncation setting for the at least one of the one or more processing layers, wherein the determining is based on an application to be executed on the machine learning network; programming the flexible bit truncation setting in the flexible bit truncation storage hardware of the at least one of the one or more processing layers; and executing the application, using the flexible bit truncation setting.

Machine learning processing is enabled using flexible bit truncation. The machine learning processing can include classifying data to be included in a class or not included in a class, drawing inferences about the data, and so on. The data can include audio data, image data, video data, and so on. The processing requirements of the data can be reduced while maintaining processing accuracy using flexible bit truncation. The flexible bit truncation truncates least significant bits (LSBs) of a data element sourced from flexible bit truncation storage hardware. The bit truncation is determined by analyzing an application to be run on a network such as a machine learning network. A bit truncation setting is determined by analyzing an application for output accuracy as the number of truncated bits is increased. A setting can include a maximum number of bits that can be terminated while maintaining high processing accuracy. The bit truncation setting is used to program flexible bit truncation storage, where the flexible bit truncation hardware sources the truncated data to a layer within a network such as a machine learning network. The application can then be executed using the flexible bit truncation setting.

A machine learning (ML) network is accessed. The ML network can be based on a processing network such as a convolutional neural network (CNN). The network can include one or more processing layers such as one or more of an input layer, an output layer, an intermediate or hidden layer, and so on. The at least one of the one or more processing layers is sourced with flexible bit truncation storage hardware. The flexible bit truncation storage hardware can truncate bits from stored data. The number of truncated bits can include zero bits, one bit, two bits, etc. A flexible bit truncation setting is determined for at least one of the one or more processing layers. A flexible bit truncation setting can be substantially equal to one or more other truncation settings or can be substantially different from other truncation settings. The determining is based on an application to be executed on the machine learning network. Different applications can process different data types, data precisions, and the like. Thus, bit truncation settings can differ between applications, data types to be processed by the applications, etc. The flexible bit truncation setting is programmed in the flexible bit truncation storage hardware of the at least one of the one or more processing layers. The programming the flexible bit truncation setting can occur in real time during application runtime. The truncation setting need not remain static throughout processing by the application. The programming the flexible bit truncation setting can change dynamically during runtime. The application is executed using the flexible bit truncation setting. The execution can produce a result such as a classification or an inference.

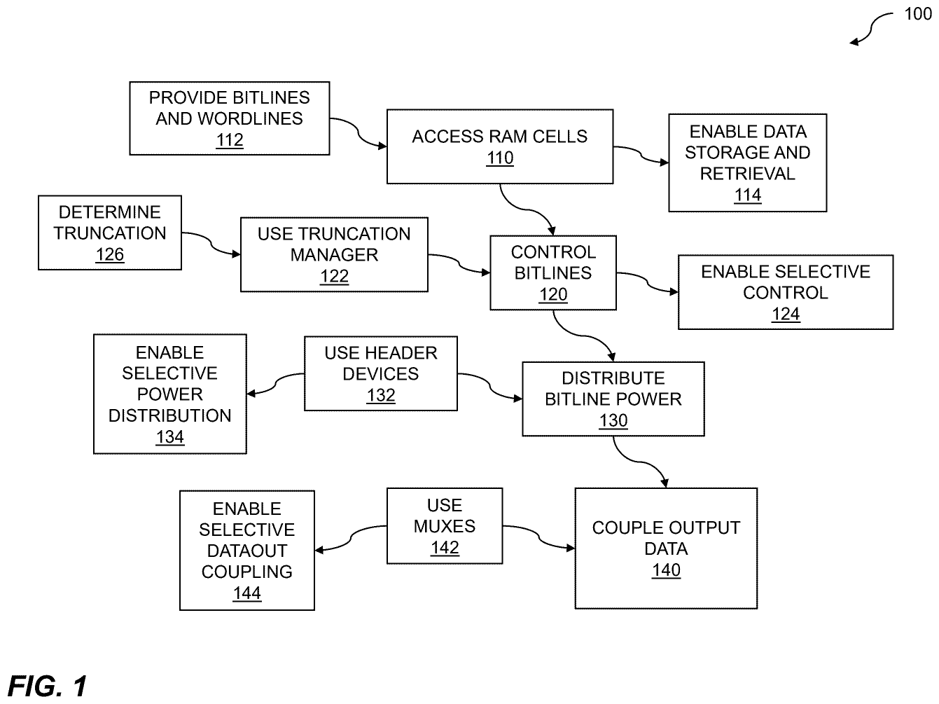

FIG. 1 is a flow diagram for a random access memory using flexible bit truncation. Data can be stored into and loaded from storage. The data can include collected data, media data such as audio data and video data, and so on. The media data can be provided to an electronic user device, at the request of the user, as a stream. In order to reduce power consumption of a storage device such as a random access memory (RAM), one or more least significant bits (LSBs) of the data stored in the RAM can be truncated. By truncating the data, circuit elements associated with the LSBs can be deselected. The deselecting of circuit elements includes electrically decoupling the LSBs. The decoupled LSBs are not accessed, so power to the LSBs is not required, thus reducing power consumption of the RAM. The deselecting of the LSBs can be based on an algorithm to maintain sufficient data integrity to meet one or more streaming requirements. The streaming requirements can be based on applications such as luminance-aware, content-aware, and region-of-interest aware video applications. The flexible bit truncation enables these video applications while maintaining a sufficient user experience (UX) when consuming the streamed media.

The flow 100 includes accessing 110 a plurality of random access memory (RAM) cells. The RAM cells can include read-write (RW) cells that can enable data to be loaded (read) and stored (written). In embodiments, the RAM cells comprise static RAM (SRAM) cells. The SRAM cells can be based on an SRAM circuit topology such as a six-transistor topology. The RAM cells are arranged in an array. In the flow 100, the array cells can provide bitlines and wordlines 112. The bitline can be used to provide and access RAM cell contents, and the wordlines provide access to the RAM cells. In the flow 100, the bitlines and wordlines are functionally accessible for data storage and retrieval 114. The wordlines enable RAM cell access, and the bitlines provide store data and obtain load data. In embodiments, the functional accessibility is based on logic circuitry coupled to power inputs, address inputs, control inputs, and data inputs and outputs. The logic circuitry can control the RAM array, provide and access data, and the like. In embodiments, the logic circuitry is further coupled to the array.

The flow 100 includes controlling 120 the bitlines within the RAM array. The controlling the bitlines can include enabling or disabling bitlines, coupling or decoupling bitlines, and so on. A truncation manager 122 is coupled to the RAM array. In the flow 100, the truncation manager is used for controlling the bitlines within the array. The truncation manager can accomplish a variety of management operations. In a usage example, the truncation manager can be used to determine if data stored within the RAM array is to be truncated by one or more LSB bits. The truncation manager can further be used to assign the optimal value for the number of truncated LSB bits. The truncation manager can comprise a plurality of truncation logic units, which are disposed near, and provide control for, each of the bitlines in the array. In embodiments, the truncation manager can control a plurality of truncation logic units. The plurality of truncation logic units can control bitlines within the RAM array. In embodiments, each truncation logic unit of the plurality of truncation logic units controls a bitline. Recall that a SRAM cell such as a six-transistor SRAM cell can be coupled to two bitlines, a true bitline and a complement bitline. The true bitline and the complement bitline are logical complements of each other. In the flow 100, the truncation manager enables selectively controlling 124 bitline power and bitline data output. The truncation manager can be controlled by one or more inputs to the truncation manager. In embodiments, the truncation manager can be controlled by one or more of the address inputs, the control inputs, and the data inputs and/or outputs. The control of the truncation manager can be accomplished using a load or store address for RAM access; control inputs such as enable, load, or store inputs; load data or store data; etc. In embodiments, the controlling the truncation manager can enable a variable number of bitlines to be deselected. The number of bitlines that can be deselected can include one bitline, two bitlines, etc.

The flow 100 includes determining a flexible bit truncation setting 126. A machine learning application can have one or more processing layers. The truncation bit setting can vary based on the machine learning application and even on which task each layer of the machine learning application is performing. In embodiments, at least two of the one or more processing layers are sourced with flexible bit truncation storage hardware. The processing layers can be processing substantially similar data types or different data types. The flexible bit truncation setting can include truncating zero LSBs, one LSB, two LSBs, and so on. The application to be executed can include an image or audio processing application, a natural language processing application, a video processing application, and so on. The determining can be based on analysis, where analysis results can be compared to a factor, a criterion, a threshold, and so on. The factor, criterion, threshold, etc. can include a convergence rate, a classification accuracy, an accuracy threshold, etc. In a usage example, a convolutional neural network model such as a VGG-16 model can be compared to a lightweight model such as a filter-pruned lightweight VGG-16 model. The models can be evaluated for different numbers of truncation bits, and the results compared for classification accuracy, inference convergence rate, etc. At least one additional flexible bit truncation setting can be determined. The flexible bit truncation setting, and the additional flexible bit truncation setting, can be applied to different layers within the machine learning network. In embodiments, the at least one additional flexible bit truncation setting can be different from the flexible bit truncation setting. The flexible bit truncation setting can be used as determined, modified, and so on.

The flexible bit truncation setting can be in communication with the flexible bit truncation storage hardware. The programming the flexible bit truncation setting can include configuring the storage hardware to provide data less the truncated bits. The programming the flexible bit truncation setting can include providing the truncation setting to a truncation manager. The truncation manager can control one or more truncation elements, where a truncation element can enable or disable one or more LSBs in the bit truncation storage hardware. The truncation manager can further select which storage outputs will be sourced to the layer in the ML network. Discussed above, the flexible bit truncation setting and the additional flexible truncation setting can be substantially similar or substantially dissimilar. The programming can occur at a convenient point in application execution on the machine learning network. The programming the flexible bit truncation setting can occur in real time during application runtime. As the application is executed on the machine learning network, requirements such as data precision requirements, classification accuracy, etc. can change. The changes can be applied to one or more layers within the machine learning network. The programming the flexible bit truncation setting can change dynamically during runtime. The dynamic change during runtime can occur for processing efficiency, relaxed precision requirements, etc.

The flow 100 includes distributing bitline power 130. Power can be distributed to a bitline precharged for loading data from a RAM cell, precharged to speed storing data into a RAM cell, and so on. In the flow 100, bitline power header devices 132 are coupled to bitlines associated with the RAM array. The bitline power header devices can include one or more devices. In embodiments, the power header devices can include a power header device pair. The power header device pair can comprise substantially similar devices or substantially dissimilar devices. In the flow 100, the bitline power header devices selectively distribute power 134 along each of the bitlines. The power distribution can include sourcing power to and sinking power from a bitline. In embodiments, a p-type power header device of the power header device pair can control source current power distribution for the bitline. A p-type power header device is chosen and designed for its ability to source power to a bitline. In other embodiments, an n-type power header device of the power header device pair can control sink current power distribution for the bitline. An n-type power header device is chosen and designed to adequately sink power from a bitline. The operating of the bitline header devices can be managed from the truncation manager. In embodiments, the controlling the truncation manager can further enable the deselected bitlines to be powered off using the bitline power header devices. The powering off of deselected bitlines reduces power consumption by being able to omit sourcing or sinking current to the bit lines.

The flow 100 includes coupling data to data outputs 140. In a usage example, a RAM can be based on more than one array of cells. The multiple arrays or “banks” can be implemented such that each bank can be accessed separately. The multiple banks can be loaded and stored separately. The multiple banks can be logically combined to form words of various widths, different numeric representations and precisions, and so on. In the flow 100, bitline output multiplexors 142 are coupled to bitline outputs of the array. The output multiplexers can select from two or more bitlines, where the two or more bitlines can be associated with the same array or RAM cells, with different arrays of RAM cells, and the like. In the flow 100, the bitline output multiplexors selectively couple the bitlines to the data outputs 144. The output multiplexers or “muxes” can be used to select which bitlines are routed to the data outputs.

The selective coupling of bitline output multiplexers and bitlines can be based on control of the truncation manager. In embodiments, the controlling the truncation manager further enables deselected bitline sense amplifiers to be isolated from logic circuitry sourcing the data outputs. The data outputs of the RAM can be coupled to one or more of a channel, a bus, a network, a port, and so on. The contents of the data outputs can be captured in buffers, loaded into registers or other storage such as cache or local memory, and the like. In embodiments, the bitline output multiplexors can be activated based on truncation logic unit results. The truncation logic results can be based on logical evaluation of one or more applications such as streaming applications. The streaming applications can include a video streaming application. Recall that video applications can include one or more video “aware” applications such as luminance-aware applications, content-aware applications, region-of-interest-aware applications, etc. The truncation logic can enable a number of LSBs to truncate from data, where the number of LSBs to be truncated can include one or more LSBs. In a usage example, bit truncation can be based on a luminance-aware technique for video data. The luminance-aware technique can truncate three or four LSBs, depending on ambient light conditions. That is, three LSBs can be truncated for the video data viewed on an overcast day, and four LSBs can be truncated for the video data viewed in full sunlight. In other embodiments, the truncation logic units can form a daisy chain of truncation logic units. Recall that a number of LSBs can be truncated from data such as video data. In a usage example, three LSBs associated with video data can be truncated. The three LSBs to be truncated can include a lefthand bit, a center or middle bit, and a righthand bit. In embodiments, the three LSBs to be truncated can include a lefthand bit, which will be one, and another two bits which will be zeros. This pattern (b′100′) can represent an optimal LSB pattern for some applications.

In embodiments, a first truncation logic unit of the daisy chain of truncation logic units can receive a signal from the truncation manager and can pass a signal on to a next truncation logic unit. The signal can include a control signal, a flag, and so on. In embodiments, the first truncation logic unit of the daisy chain of truncation logic units can control a bitline representing the most significant bit of a data word. Each bit within the data word can have a truncation logic unit associated with it. In embodiments, a next truncation logic unit of the daisy chain of truncation logic units can control a next most significant bit of a data word. The daisy chain of truncation logic units continues for each next bit within the data word. In a usage example, the daisy chain of truncation logic units progresses from the truncation unit associated with the MSB of a RAM word to the truncation unit associated with the LSB of the RAM word. That is, in embodiments, a last truncation logic unit of the daisy chain of truncation logic units can control a bitline representing the least significant bit of a data word.

In embodiments, the daisy chain of truncation logic units can include a head input, a tail input, and a tail output. The head input can include one or more inputs and/or outputs, where the inputs and/or outputs can provide data, control signals, and so on. The head inputs may originate from the truncation manager based on the number of bits desired to be truncated. The tail inputs may originate from a previous or “upstream” stage of the daisy chain of truncation logic units and can be generated based on a logic truth table (described later). In embodiments, the truncation manager can source each head input of each truncation logic unit. In a usage example, and as is shown in a figure illustrating a memory structure, the head input and the tail input from the previous daisy chain stage is coupled to the truncation unit associated with a current stage. The tail output of a given stage can be provided to a “downstream” stage of the daisy chain. In other embodiments, the tail output of each truncation logic unit in the daisy chain of truncation logic units can source the head input of a next truncation logic unit in the daisy chain of truncation logic units, except the last truncation logic unit in the daisy chain of truncation logic units. The tail output of the last truncation logic unit is not coupled to a next truncation logic unit because there are no truncation logic units downstream of the last or LSB truncation logic unit.

Various steps in the flow 100 may be changed in order, repeated, omitted, or the like without departing from the disclosed concepts. Various embodiments of the flow 100 can be included in a computer program product embodied in a non-transitory computer readable medium that includes code executable by one or more processors. Various embodiments of the flow 100, or portions thereof, can be included on a semiconductor chip and implemented in special purpose logic, programmable logic, and so on.

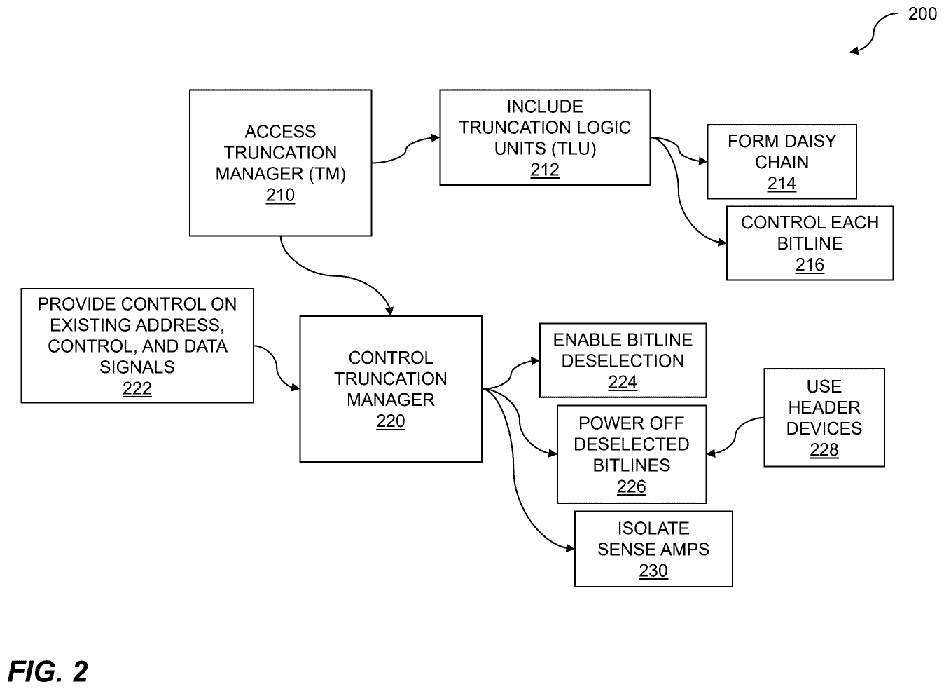

FIG. 2 is a flow diagram for truncation manager usage. Power consumption by an electronic device such as a memory impacts design of the memory, usage of the memory, and so on. The memory can be used in a variety of electronic devices including personal electronic devices. The personal electronic devices include smartphones, tablet computers, laptop computers, and so on. Since these personal electronic devices, particularly handheld devices, are small and powered by batteries, power consumption is a paramount concern due to device heating and battery operating time. By truncating data, power consumption, and, by extension, heat dissipation can be reduced. The data truncation can be managed by a truncation manager which handles data manipulation such as data truncation. The truncation manager supports a random access memory using flexible bit truncation. A plurality of random access memory (RAM) cells arranged in an array is accessed. The array cells include bitlines and wordlines, where the bitlines and wordlines are functionally accessible for data storage and retrieval. The functional accessibility is based on logic circuitry coupled to power inputs, address inputs, control inputs, and data inputs and outputs. The logic circuitry is further coupled to the array to control and operate the array. A truncation manager is coupled to the RAM array for controlling the bitlines within the array. The truncation manager includes locally distributed truncation logic units. The truncation manager selectively controls bitline power and bitline data output through a plurality of truncation logic units. Bitline power header devices are coupled to the RAM array. Bitline output multiplexors are coupled to the RAM array. The bitline output multiplexors selectively couple the bitlines to the data outputs.

The flow 200 includes accessing a truncation manager 210. The truncation manager can control bitline power and bitline data output for bitlines associated with the RAM cells arranged in an array. The truncation manager can include a core, a module, an integrated circuit, an ASIC, an FPGA, and so on. In the flow 200, the truncation manager controls a plurality of truncation logic units 212. The plurality of truncation logic units, which can include logic circuitry within the truncation manager, coupled to the truncation manager, etc., can manipulate the bitline power, the bitline data output, and so on.

In the flow 200, the truncation logic units form a daisy chain 214 of truncation logic units. Recall that the truncation manager can be used to determine a number of least significant bits (LSBs) that can be truncated in order to reduce power consumption by a RAM. The truncation manager can determine which LSB bitlines should be truncated and can provide one or more truncation signals. The daisy chain can provide location communication between and among LSBs to facilitate the truncating. In the flow 200, each truncation logic unit of the plurality of truncation logic units can control a bitline 216. The truncation logic units can enable power control using one or more electronic devices. Discussed previously, the bitline power can be controlled using power header devices. The power header devices can comprise a power header device pair. The power header device pair can include a p-type device for sourcing power to a bitline, and an n-type device for sinking power from a bitline.

In the flow 200, the truncation manager is controlled 220. The truncation manager can be controlled by signals originating externally from the array. For example, if the array is a standalone array, the signals may be communicated on existing array inputs and outputs using a special “load mode” or a typically-available test mode. And if the array is embedded along with other control and processing logic, the signals may be communicated directly from such logic. The control of the truncation manager can be based on one or more flags such as status flags, signals such as control signals, and the like. The flags, signals, etc. can be provided as inputs and outputs to the truncation manager. In the flow 200, the truncation manager is controlled 222 by one or more of the existing address inputs, control inputs, and data inputs and/or outputs. The various inputs and outputs that can be provided to the truncation manager can enable the truncation manager to manipulate the bitlines of the RAM array. The control 222 can set up the truncation manager, and thus its associated truncation logic units, to control which bitlines are to be truncated from storage within the array. In the flow 200, the controlling the truncation manager enables a variable number of bitlines to be deselected 224. Discussed previously and throughout, one or more LSBs can be truncated from data loaded from the RAM. The truncating LSBs can be based on an application such as a video application, where the video application can include an “aware” application such as luminance-aware, content-aware, and region-of-interest-aware applications, etc. In the flow 200, the controlling the truncation manager further enables the deselected bitlines to be powered off 226 using the bitline power header devices. The powering off the bitlines can reduce power consumption, and by extension, heat dissipation by the RAM. The reducing the power consumption can include avoiding sourcing current to and/or sinking current from the deselected bitlines.

In the flow 200, the controlling the truncation manager further enables the deselected bitlines to be powered off using the bitline power header devices 228. The power header devices can include one or more electronic devices. In embodiments, the power header devices can include a power header device pair. The power header device pair can include complementary devices such as a p-type device and an n-type device. In embodiments, a p-type power header device of the power header device pair can control source current power distribution for the bitline. A p-type device can be used to “pull up” a line such as a bitline by sourcing current to the bitline. In other embodiments, an n-type power header device of the power header device pair can control sink current power distribution for the bitline. An n-type device can be used to “pull down” a line such as a bitline by sinking current from the bitline. In the flow 200, the controlling the truncation manager can further enable deselected bitline sense amplifiers to be isolated 230 from logic circuitry sourcing the data outputs. Recall that a RAM cell such as an SRAM cell can access a true bitline and a complement bit line for storing data and for loading data. A sense amplifier can be coupled, via a selection multiplexer, to the true bitline and to the complement bitline. The sense amplifier can use these bitlines to determine the contents of the SRAM cell. When bitlines are deselected, the contents of the SRAM cell are not read, so the sense amplifier is not needed. As a result, the sense amplifier associated with the deselected bitlines can be isolated from the RAM array outputs.

Various steps in the flow 200 may be changed in order, repeated, omitted, or the like without departing from the disclosed concepts. Various embodiments of the flow 200 can be included in a computer program product embodied in a non-transitory computer readable medium that includes code executable by one or more processors. Various embodiments of the flow 200, or portions thereof, can be included on a semiconductor chip and implemented in special purpose logic, programmable logic, and so on.

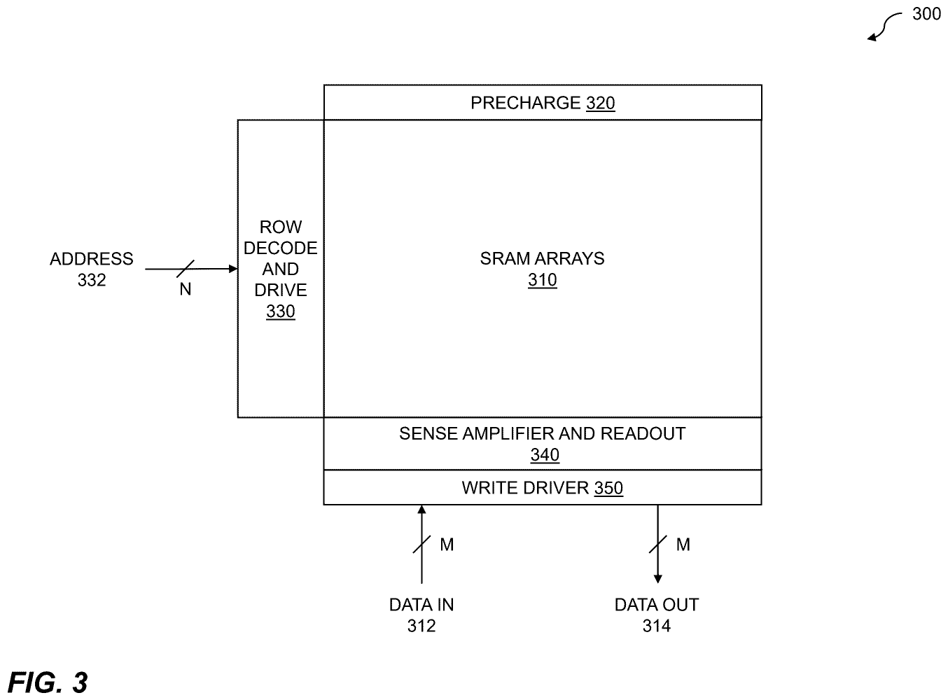

FIG. 3 illustrates a memory structure. The memory structure can comprise a static RAM (SRAM). The SRAM can include flexible bit truncation capabilities. The SRAM can be embedded with processing logic on a chip, can comprise a standalone device, can be stacked with a logic chip or additional memory chips in a separate package, and so on. The SRAM can enable random address memory using flexible bit truncation. A plurality of random access memory (RAM) cells arranged in an array is accessed. The array cells include bitlines and wordlines, where the bitlines and wordlines are functionally accessible for data storage and retrieval. The functional accessibility is based on logic circuitry coupled to power inputs, address inputs, control inputs, and data inputs and outputs. The logic circuitry is further coupled to the array to control and operate the array. A truncation manager is coupled to the RAM array for controlling the bitlines within the array. The truncation manager selectively controls bitline power and bitline data output. Bitline power header devices are coupled to the RAM array. Bitline output multiplexors are coupled to the RAM array. The bitline output multiplexors selectively couple the bitlines to the data outputs.

The system block diagram 300 includes SRAM arrays 310. The SRAM arrays 310 can be based on various circuit topologies. In a usage example, the SRAM arrays are based on six-transistor SRAM cells. The SRAM arrays can have access to data input lines such as data in 312. The data input lines can provide data to the SRAM arrays for storing the data in the SRAM arrays. The data input lines can include M data input lines. The SRAM arrays can have access to data output lines such as data out 314. The data output lines can be used to load (read) data from the SRAM arrays and provide that data at the outputs of the SRAM. The data output lines can include M data output lines. The data in and data out lines can be unidirectional or bidirectional. The system block diagram 300 can include precharge 320. Precharge can be used to set a voltage on bitlines of the SRAM array. The set or “precharge” voltage is used to enable loading of contents of the SRAM to be accomplished faster and more reliably compared to not setting bitline voltages. In embodiments, the bitlines are precharged using bitline power header devices. The bitline power header devices can include a pair of devices, where one device can include a p-type device. The p-type device of the header pair can source current to a bitline. The other device of the header pair can include an n-type device. The n-type device can sink current from a bitline.

The system block diagram 300 can include row decoders and row drivers 330. The row decoders select one or more wordlines associated with the RAM array. The decoders receive an address 332, where the address can include a number of bits such as N bits. The selected wordline or wordlines enable access to RAM cells that are coupled to the one or more wordlines. The RAM cell access supports storing data on bitlines into the RAM cells, and loading data stored in the RAM cells onto bitlines. The row drivers energize a wordline or wordlines selected by the decoder. The drivers speed transmission of a selection signal along wordline. The system block diagram can include sense amplifiers and readout logic. A sense amplifier detects a small signal change such as a small voltage change on at least one bitline. Based on the direction of the small signal change, such as an increase or a decrease in voltage, the sense amplifier amplifies the small signal change to quickly indicate a value read from a RAM cell. A sense amplifier can access both the true bitline and the complement bitline associated with a RAM cell. Such a sense amplifier differentially reads the true bitline and the complement bitline, thereby speeding up the determination of the contents of the RAM cell. In a usage example, a precharge voltage is placed on a true bitline and on a complement bitline associated with a RAM cell. A RAM cell is selected using a wordline. The precharge voltage on the true bit changes slightly either up or down. The precharge voltage on the complement bitline changes in a direction opposite of the change of the true bitline. The resulting voltage differential enables the sense amplifier to quickly change from the slight voltage changes to a full voltage swing on the bitlines.

Continuing with block 340, the block includes a readout capability. In embodiments, the readout capability is enabled by bitline output multiplexers, where the bitline output multiplexors selectively couple the bitlines to data outputs. A multiplexer can select from a plurality of bitlines and direct the selected bitline value to a data output line of the RAM. The plurality of multiplexers can be used to select a group of associated bits within RAM cells. The associated bits can include a byte, a half word, a word, a double word, and so on. The system block diagram 300 can include write drivers 350. The write drivers can be used to write data received on data input lines such as the data in lines 312 discussed above. The write drivers speed the storing of data into one or more RAM cells.

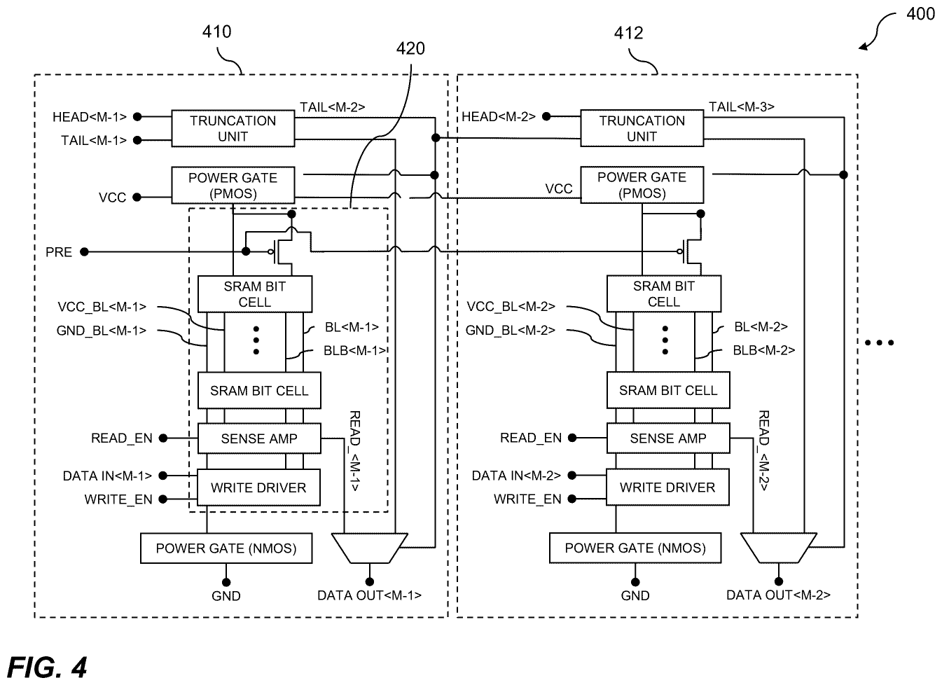

FIG. 4 is a system block diagram showing truncation management and power gating. The memory structure shown in the system block diagram can include a plurality of random access memory (RAM) cells that are arranged in an array. The RAM cells can be static RAM cells (SRAM). The memory structure can further include precharge elements, row decoders and drivers, bitlines, sense amplifiers and readout multiplexers, write drivers, and so on. The memory structure can further include a truncation manager. The truncation manager can comprise a truncation unit disposed for controlling each bitline. The truncation manager can selectively control power distribution to each bitline within the RAM array. The truncation manager can further selectively couple the bitlines to data outputs. The selective coupling can be accomplished using multiplexers. The memory structure can support a random access memory using flexible bit truncation. A plurality of random access memory (RAM) cells arranged in an array is accessed. The array cells include bitlines and wordlines, where the bitlines and wordlines are functionally accessible for data storage and retrieval. The functional accessibility is based on logic circuitry coupled to power inputs, address inputs, control inputs, and data inputs and outputs. The logic circuitry is further coupled to the array to control and operate the array. A truncation manager is coupled to the RAM array for controlling the bitlines within the array. The truncation manager selectively controls bitline power and bitline data output. Bitline power header devices are coupled to the RAM array. Bitline output multiplexors are coupled to the RAM array. The bitline output multiplexors selectively couple the bitlines to the data outputs.

Discussed previously and throughout, least significant bits (LSBs) can be truncated from data as the data is written, stored, and read from a RAM such as a static RAM (SRAM). The LSBs of the data can be truncated in order that power consumption of the RAM can be reduced, while the quality of the data can be sufficiently maintained. In a usage example, one or more LSBs of the data can be truncated from data associated with a stream such as a video stream. The selection of the number of LSBs to truncate can be based on viewing quality, and by extension user experience (UX) of a user viewing the video stream. The truncation can be accompanied by power gating to reduce power consumption. The truncation management and the power gating enable a random access memory using flexible bit truncation. A plurality of random access memory (RAM) cells arranged in an array is accessed. The array cells include bitlines and wordlines, where the bitlines and wordlines are functionally accessible for data storage and retrieval. The functional accessibility is based on logic circuitry coupled to power inputs, address inputs, control inputs, and data inputs and outputs. The logic circuitry is further coupled to the array to control and operate the array. A truncation manager is coupled to the RAM array for controlling the bitlines within the array. The truncation manager selectively controls bitline power and bitline data output. Bitline power header devices are coupled to the RAM array. Bitline output multiplexors are coupled to the RAM array. The bitline output multiplexors selectively couple the bitlines to the data outputs.

The system block diagram 400 shows a memory structure based on SRAM cell columns. While two columns of SRAM cells are shown, SRAM cell column 410 and SRAM cell column 412, other numbers of SRAM cell columns can be included. The “cell columns” can be based on SRAM cells coupled to common bitlines, and the logic circuits to support storing data into the SRAM cells and loading data from the SRAM cells. The common bitlines can include a true bitline and a complement bitline. The number of SRAM cell columns included in the memory structure can be based on a size of a data object such as a byte, a word, a double word, and so on. The number of SRAM cell columns can include a multiple of the size of the data object. An SRAM cell column such as 420 can include a precharge device, a plurality of SRAM bit cells, a sense amplifier, and a write driver. In order to enable the SRAM columns to support flexible bit truncation, additional logic elements can be added to the SRAM columns. In embodiments, a truncation logic unit is coupled to the SRAM cell column. The truncation logic unit can receive control signals from the truncation manager and from another SRAM column. The truncation logic unit can selectively control bitline power to the bitlines in the SRAM column. The selective control of bitline power can be accomplished using one or more power header devices. In embodiments, the power header devices can include a power header device pair. One device of the device pair can source current to the bitline from a source such as VCC. The other device of the device pair can sink current from the bitline to a “source” such as ground. In a usage example, the power header devices can selectively isolate the bitline from power distribution. The selectively isolating the power distribution can reduce power consumption by the SRAM cell column. The truncation logic unit can further selectively control bitline data output. In a usage example, the SRAM cell column is to be truncated. The data out can include a signal such as a tail signal indicating that no data is provided. If the SRAM cell column is not truncated, then the output comprises the data.

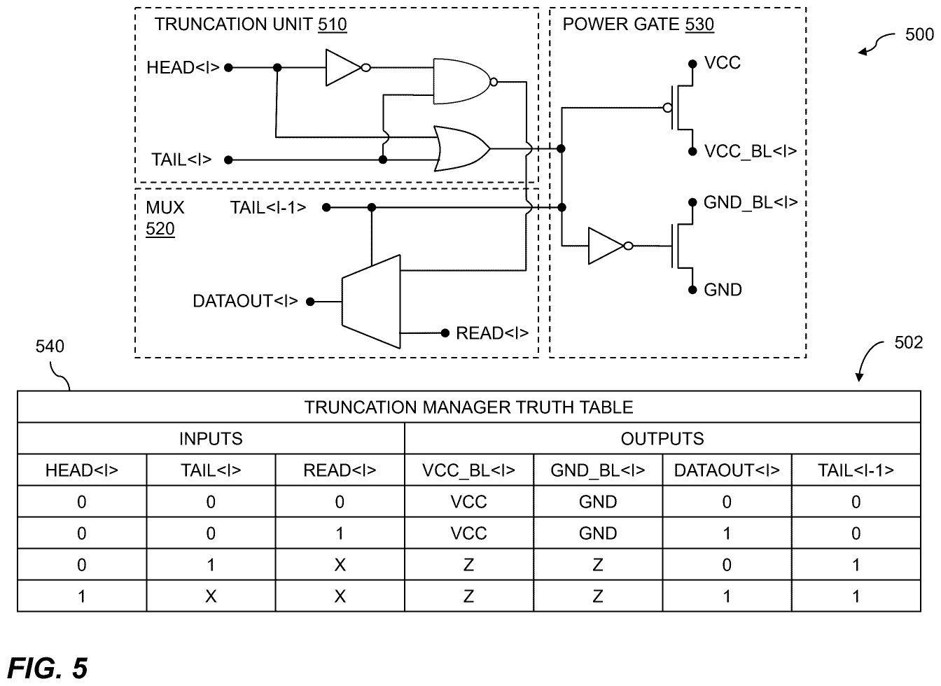

FIG. 5 shows truncation manager circuitry and a truth table. A truncation manager can be coupled to a random access memory (RAM). The truncation manager can selectively control bitline power to and bitline data output from one or more least significant bits of data. The data can include alphanumeric data, audio data, video data, and so on. The bitline power and bitline data output can be controlled in order to reduce RAM power consumption, RAM heat dissipation, and so on. The truth table shows inputs to and outputs from the truncation manager circuitry. The truncation manager circuitry and the truth table enable a random access memory using flexible bit truncation. A plurality of random access memory (RAM) cells arranged in an array is accessed. The array cells include bitlines and wordlines, where the bitlines and wordlines are functionally accessible for data storage and retrieval. The functional accessibility is based on logic circuitry coupled to power inputs, address inputs, control inputs, and data inputs and outputs. The logic circuitry is further coupled to the array to control and operate the array. A truncation manager is coupled to the RAM array for controlling the bitlines within the array. The truncation manager selectively controls bitline power and bitline data output. Bitline power header devices are coupled to the RAM array. Bitline output multiplexors are coupled to the RAM array. The bitline output multiplexors selectively couple the bitlines to the data outputs.

Truncation manager circuitry is shown 500. The truncation manager circuitry can control the bitline of the RAM array. The truncation manager controls three blocks that in turn access and control a bitline. These three blocks can be repeated for each bitline within the RAM. The three blocks can include a truncation logic unit 510. The truncation logic unit controls selective distribution of power along each of the bitlines. The truncation logic unit further controls bitline output selection. The truncation logic unit can receive as inputs a head value such as head<i>, and a tail value such as tail<i>. The truncation circuitry further includes a multiplexer 520. The multiplexer selectively couples the bitline to the data output. The multiplexer can be controlled by a tail bit such as tail<i-1>. The multiplexer selects between the output of the truncation logic unit, and a data bit loaded from the RAM. The output of the multiplexer is provided to an output line such as dataout<i>. The truncation manager circuit further includes a power gate 530. The power gate is also referred to throughout as the power header devices. In embodiments, the power header devices comprise a power header device pair. The power header device pair can include different or complementary devices such as a p-type device and an n-type device. In embodiments, the p-type power header device of the power header device pair can control source current power distribution for the bitline. The p-type device can act as a pullup device for the bitline. In other embodiments, the n-type power header device of the power header device pair can control sink current power distribution for the bitline. The n-type device can act as a pulldown device. The p-type device can be coupled between a high voltage such as VCC and the bitline. The n-type device can be coupled to the bitline and a low voltage such as ground.

The figure further shows a truth table 502 for the truncation manager circuitry. The truth table includes inputs and outputs 540. The truth table further shows possible values for inputs, and the resulting values for the outputs. The inputs to the truncation manager truth table can include a head signal such as head<i>. The head signal can be generated by the truncation manager. The inputs can further include a tail signal such as tail<i>. The tail signal can be provided by the truncation manager, can be received from a previous truncation logic unit, and so on. The inputs can further include a read signal such as read<i>. The read signal can be used by the multiplexer to select data read from the RAM of the output of the truncation logic unit. The truth table can include outputs such as bitline outputs, data out, and a tail output. The bitline outputs can indicate that a bitline is connected to VCC, such as vcc_bl<i>. The bitline outputs can further indicate that a bitline is connected to ground such as gnd_bl<i>. The remaining outputs shown in the truth table can include data out and tail. Data out such as dataout<i> can include a tail output indication or data loaded from a RAM cell. The remaining output shown, a tail, such as tail<i-1>, can be provided to the next least significant bit in the data. The tail bit can be used to indicate that the next least LSB is to be truncated.

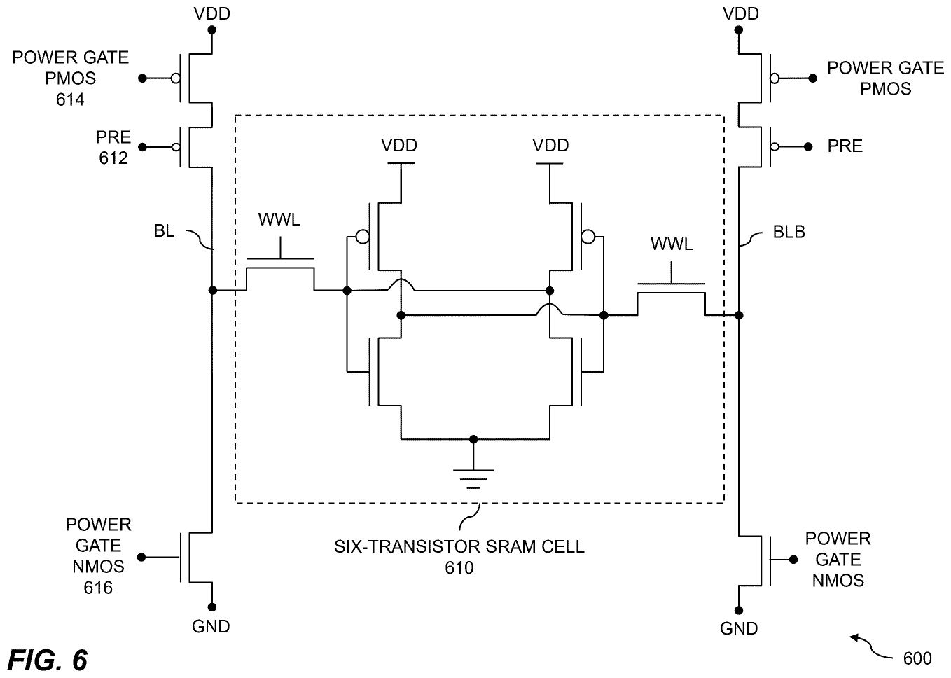

FIG. 6 illustrates a six-transistor bit cell with power gates. A memory cell such as a RAM cell is based on a circuit topology. Discussed previously and throughout, the RAM cell can include a static RAM (SRAM) cell. The RAM cell can store data as a voltage, where a high voltage can represent a logical value such as a logic one, and a low voltage can represent another logical value such as a logic zero. In addition, the RAM can access one or more bitlines, where the bitlines can be used to store (write) data into the RAM and to load (read) data from the RAM. Access by the RAM to the bitlines is enabled by a word line. The RAM cell can be one of a plurality of RAM cells within an array that forms the RAM. The RAM is enabled using flexible bit truncation. The flexible bit truncation enables power consumption reduction within the RAM. A plurality of random access memory (RAM) cells arranged in an array is accessed. The array cells include bitlines and wordlines, where the bitlines and wordlines are functionally accessible for data storage and retrieval. The functional accessibility is based on logic circuitry coupled to power inputs, address inputs, control inputs, and data inputs and outputs. The logic circuitry is further coupled to the array to control and operate the array. A truncation manager is coupled to the RAM array for controlling the bitlines within the array. The truncation manager selectively controls bitline power and bitline data output. Bitline power header devices are coupled to the RAM array. Bitline output multiplexors are coupled to the RAM array. The bitline output multiplexors selectively couple the bitlines to the data outputs.

A six-transistor RAM bit cell with power gates is shown 600. The bit cell can include a six-transistor RAM cell 610. The six-transistor (6T) RAM cell, such as the six-transistor SRAM cell shown, can be based on two cross-coupled inverters and two pass transistors. The cross-coupled inverters statically hold a logical value such as a logic one or a logic zero. The 6T bit cell with power gates (discussed below) can be used to store bits such as least significant bits (LSBs) of data, where the data can include a byte, a word, a double word, etc. The 6T SRAM cells can be fabricated in a variety of semiconductor technologies such as CMOS technologies. The CMOS technologies can be based on a range of feature sizes. A feature size associated with a CMOS technology can include a 45 nm feature size. The 6T cells can be controlled by write/read wordlines (WWLs). When the wordline is enabled, the contents of the 6T call can perturb a pair of bitlines. The bitlines can include a true bitline (BL) and a complemented or “barred” bitline (BLB). The bitlines of a 6T cell can be coupled to a differential sense amplifier (not shown) that can resolve the value of the contents of the 6T cell as a logic one value or a logic zero value. The transistors associated with the cross-coupled inverters and the transistors can be sized to increase read access speed, data integrity, and so on. In embodiments, the PMOS pullup (PU) devices of the cross-coupled inverters can include a shape factor (e.g., W/L) of 100 nm/50 nm. The NMOS pulldown (PD) devices associated with the inverters can include a shape factor of 200 nm/50 nm. The pass transistors that accomplish access to the 6T storage cells can include a shape factor of 150 nm/50 nm.

Prior to loading data from the SRAM cell, bitlines BT and BTB can be precharged to a precharge voltage. The precharge voltage can be chosen to minimize disturbance of the bit loaded into the RAM while maximizing effectiveness of the transfer of the bit value to the bitlines. Each bitline can be charged using a precharge device such as a PMOS device. The precharge signal such as PRE 612 can be coupled to a bitline to precharge the bitline to the desired precharge voltage. Recall that one or more LSBs associated with data such as video data can be truncated. The truncating the LSBs reduces power consumption by the RAM while maintaining a quality level that enhances user experience. The truncating LSBs is accomplished using power header devices. In embodiments, the bitline power header devices can selectively distribute power along each of the bitlines. The power header devices can include PMOS devices, NMOS devices, and a combination of PMOS and NMOS devices. In embodiments, the power header devices can include a power header device pair. In the diagram, the power header device pair can include PMOS device 614 and NMOS device 616. In embodiments, the p-type power header device of the power header device pair can control source current power distribution for the bitline. The PMOS device 614 can be used as a pullup device. In other embodiments, the n-type power header device of the power header device pair can control sink current power distribution for the bitline. The NMOS device 616 can be used as a pulldown device.

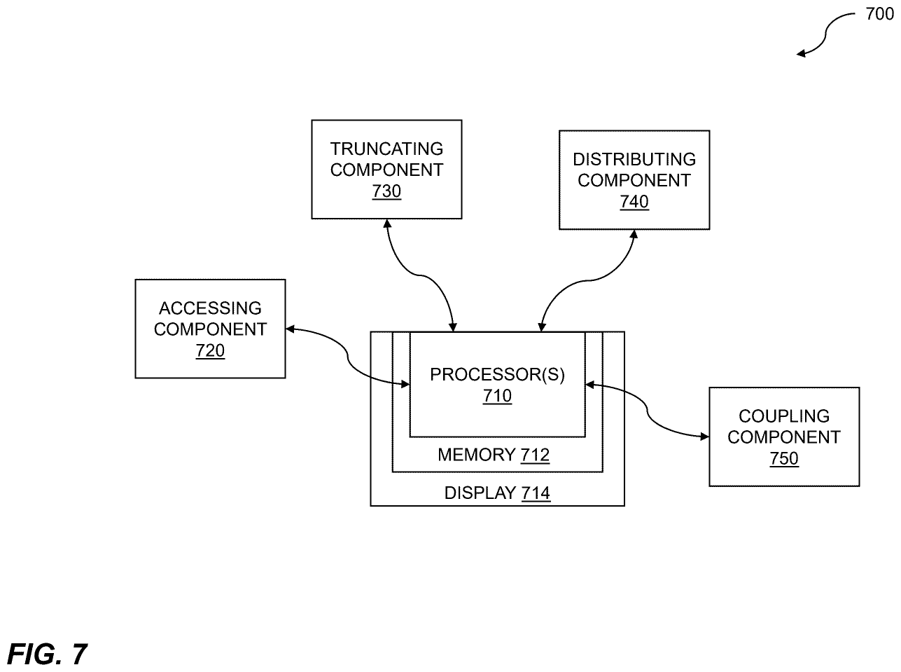

FIG. 7 is a system diagram for data manipulation. The data manipulation is enabled by a random access memory using flexible bit truncation. The system 700 can include one or more processors 710, which are coupled to a memory 712 that stores instructions. The system 700 can further include a display 714 coupled to the one or more processors 710 for displaying data, truncated data, untruncated data, head inputs, tail inputs, tail outputs, and so on. In embodiments, one or more processors 710 are coupled to the memory 712, wherein the one or more processors, when executing the instructions which are stored, are configured to: access a plurality of random access memory (RAM) cells arranged in an array, wherein the array cells comprise bitlines and wordlines, wherein the bitlines and wordlines are functionally accessible for data storage and retrieval, wherein the functional accessibility is based on logic circuitry coupled to power inputs, address inputs, control inputs, and data inputs and outputs, and wherein the logic circuitry is further coupled to the array; couple a truncation manager for controlling the bitlines within the array, wherein the truncation manager selectively controls bitline power and bitline data output; couple bitline power header devices, wherein the bitline power header devices selectively distribute power along each of the bitlines; and couple bitline output multiplexors, wherein the bitline output multiplexors selectively couple the bitlines to the data outputs.

The system 700 can include an accessing component 720. The accessing component can access a plurality of random access memory (RAM) cells. The RAM cells can be arranged in an array. The RAM cells can include read-write RAM cells that store data and provide data. In embodiments, the RAM cells comprise static RAM (SRAM) cells. The SRAM cells can be implemented using various SRAM technologies. The SRAM technology can include a CMOS technology. In a usage example, an SRAM based on a CMOS technology can include two inverters in a cross-coupled configuration and two pass transistors. The SRAM can be used to store various datatypes such as characters, symbols, numbers, and so on. The numbers can be written and read based on a variety of numeric representations such as integer, real, floating-point, single-precision, double-precision, etc. The SRAM can store data such as audio data, video data, and the like.

In embodiments, the array cells can include bitlines and wordlines. The bitlines can include a true bitline and a complement bitline. The bitlines can provide data to be written into an SRAM cell and can read data from the SRAM cell. A plurality of bits, such as an 8-bit byte, a 16-bit word, etc., can be selected by the wordlines. In embodiments, the bitlines and wordlines can be functionally accessible for data storage and retrieval. The wordlines are used to access the SRAM bit cells for loading (reading) and for storing (writing) data. In embodiments, the functional accessibility can be based on logic circuitry coupled to power inputs, address inputs, control inputs, and data inputs and outputs. The logic circuitry can enable or disable power inputs; decode load addresses and store addresses provided via the address lines; enable or disable control inputs such as enable inputs; enable or disable data inputs and data outputs, etc. In further embodiments, the logic circuitry can be further coupled to the array. The logic circuitry can enable data loading and data storing; variable data truncation (discussed below), etc.

The system 700 can include a truncating component 730. The truncating component can couple a truncation manager for controlling the bitlines within the array. Recall that each SRAM cell can be selectively coupled to a pair of bitlines: bitline true and bitline complement. The truncation manager can couple or decouple one or more lines associated with SRAM cells. In embodiments, the truncation manager can selectively control bitline power and bitline data output. Bitline power can be used for precharging bitlines pairs associated with the SRAM cells. The bitline data outputs can be coupled to or decoupled from bitline sense logic circuitry such as sense amplifiers. In embodiments, the truncation manager can control a plurality of truncation logic units. The truncation logic units can be used to truncate one or more least significant bits (LSBs) from data stored in the SRAM. In a usage example, a truncation logic unit can be associated with a plurality of SRAM bits, where the column of SRAM bits can include a “column” of SRAM bits. In embodiments, each truncation logic unit of the plurality of truncation logic units can control a bitline. In a usage example, a truncation logic unit can control a true bitline, and a second truncation logic unit can control a complement bitline, where the true bitline and the complement bitline are associated with one or more SRAM cells.

The truncation manager can be controlled using one or more logic signals. In embodiments the truncation manager can be controlled by one or more of the address inputs, the control inputs, and the data inputs and/or outputs. The address inputs, the control inputs, and the data inputs and/or outputs can be provided by a controller, a processor, and so on. In embodiments, the controlling the truncation manager can enable a variable number of bitlines to be deselected. Recall that data such as video data stored in the SRAM array can be truncated. The truncation can include truncating one or more LSBs of the data. The truncating can accomplish power consumption reduction while still maintaining data quality requirements. In a usage example, three LSBs can be truncated from data associated with a video stream while still maintaining quality requirements of luminance-aware, content-aware, or region-of-interest-aware video applications. In embodiments, the controlling the truncation manager can further enable the deselected bitlines to be powered off using the bitline power header devices. Powering off bitline power header devices reduces power consumption by preventing unneeded bitlines from being precharged prior to reading or loading data from SRAM cells. In other embodiments, the controlling the truncation manager can further enable deselected bitline sense amplifiers to be isolated from logic circuitry sourcing the data outputs. Deselecting the sense amplifiers prevents the sense amplifiers from switching, thereby reducing power consumption. In embodiments, the truncation manager can enable flexible bit truncation within the array cells.

The system 700 can include a distributing component 740. The distributing component can selectively distribute power along each of the bitlines. The distributing is accomplished by coupling bitline power header devices to each of the bitlines. The bitlines can include the true bitlines and the complement bitlines. Recall that power can be distributed to bitlines prior to loading data from an SRAM cell. The power is distributed such that when the contents of an SRAM cell are enabled to the bitlines via pass transistors associated with the SRAM cell, the voltage on the bitlines, bitline true and bitline complement, are slightly disturbed in opposite directions. That is, the voltage on one bitline rises while the voltage on the other bitline drops. When designed properly, the contents of the SRAM cell recover when the SRAM cell is disconnected from the bitlines. Power can be distributed to the bitlines, or not when the bitlines are selectively decoupled by the truncation manager, using pullup devices and pulldown devices. In embodiments, the power header devices can include a power header device pair. The pullup devices can include p-type devices such as PMOS devices, while the pulldown devices can include n-type devices such as NMOS devices. The PMOS device and the NMOS device can comprise a power header device pair. In embodiments, a p-type power header device of the power header device pair can control source current power distribution for the bitline. In other embodiments, an n-type power header device of the power header device pair can control sink current power distribution for the bitline.

The system 700 can include a coupling component 750. The coupling component can couple bitline output multiplexors. The bitline output multiplexers can select bitlines from among the plurality of bitlines within the RAM. The bitline output multiplexors can selectively couple the bitlines to the data outputs. The data outputs of the RAM can be provided to a bus or network, captured in buffers, loaded into registers or other storage, and so on. In embodiments, the bitline output multiplexors can be activated based on truncation logic unit results. The truncation logic can determine a number of LSBs to truncate from data. In a usage example, bit truncation can be based on a luminance-aware technique for video data. Depending on ambient light conditions, three LSBs can be truncated for the video data viewed on an overcast day, and four LSBs can be truncated for the video data viewed in full sunlight. In embodiments, the truncation logic units can form a daisy chain of truncation logic units. Recall that a number of LSBs can be truncated from data such as video data.

In embodiments, a first truncation logic unit of the daisy chain of truncation logic units can receive a signal from the truncation manager and can pass a signal on to a next truncation logic unit. The signal can include a control signal, a flag, and so on. In embodiments, the first truncation logic unit of the daisy chain of truncation logic units can control a bitline representing the most significant bit of a data word. Each bit within the data word can have a truncation logic unit associated with it. In embodiments, a next truncation logic unit of the daisy chain of truncation logic units can control a next most significant bit of a data word. The daisy chain of truncation logic units continues for each next bit within the data word. In a usage example, the daisy chain of truncation logic units progresses from the truncation unit associated with the MSB of a RAM word to the truncation unit associated with the LSB of the RAM word. That is, in embodiments, a last truncation logic unit of the daisy chain of truncation logic units can control a bitline representing the least significant bit of a data word.

In embodiments, the daisy chain of truncation logic units can include a head input, a tail input, and a tail output. The head input can include one or more inputs and/or outputs, where the inputs and/or outputs can provide data, control signals, and so on. The head input can be sourced externally, and the tail input can be sourced from a tail output of a previous or “upstream” stage of the daisy chain of truncation logic units. In embodiments, the truncation manager can source each head input of each truncation logic unit. In a usage example, and as is shown in a figure illustrating a memory structure, the head input and the tail input from the previous daisy chain stage is coupled to the truncation unit associated with a current stage. The tail output of a given stage can be provided to a “downstream” stage of the daisy chain. In other embodiments, the tail output of each truncation logic unit in the daisy chain of truncation logic units can source the head input of a next truncation logic unit in the daisy chain of truncation logic units, except the last truncation logic unit in the daisy chain of truncation logic units. The tail output of the last truncation logic unit is not coupled to a next truncation logic unit because there are no truncation logic units downstream of the last or LSB truncation logic unit.

The system 700 can include a computer program product embodied in a non-transitory computer readable medium for data manipulation, the computer program product comprising code which causes one or more processors to generate semiconductor logic for: implementing a plurality of random access memory (RAM) cells arranged in an array, wherein the array is comprised of bitlines and wordlines, wherein the bitlines and wordlines are functionally accessible for data storage and retrieval, wherein the functional accessibility is based on logic circuitry coupled to power inputs, address inputs, control inputs, and data inputs and outputs, and wherein the logic circuitry is further coupled to the array; implementing a truncation manager for controlling bitlines within the array, wherein the truncation manager selectively controls bitline power and bitline data output; implementing bitline power header devices, wherein the bitline power header devices selectively distribute power along each bitline; and implementing bitline output multiplexors, wherein the bitline output multiplexors selectively couple bitline data to the data outputs.

Each of the above methods may be executed on one or more processors on one or more computer systems. Embodiments may include various forms of distributed computing, client/server computing, and cloud-based computing. Further, it will be understood that the depicted steps or boxes contained in this disclosure's flow charts are solely illustrative and explanatory. The steps may be modified, omitted, repeated, or re-ordered without departing from the scope of this disclosure. Further, each step may contain one or more sub-steps. While the foregoing drawings and description set forth functional aspects of the disclosed systems, no particular implementation or arrangement of software and/or hardware should be inferred from these descriptions unless explicitly stated or otherwise clear from the context. All such arrangements of software and/or hardware are intended to fall within the scope of this disclosure.

The block diagram and flow diagram illustrations depict methods, apparatus, systems, and computer program products. The elements and combinations of elements in the block diagrams and flow diagrams show functions, steps, or groups of steps of the methods, apparatus, systems, computer program products and/or computer-implemented methods. Any and all such functions—generally referred to herein as a “circuit,” “module,” or “system”—may be implemented by computer program instructions, by special-purpose hardware-based computer systems, by combinations of special purpose hardware and computer instructions, by combinations of general-purpose hardware and computer instructions, and so on.

A programmable apparatus which executes any of the above-mentioned computer program products or computer-implemented methods may include one or more microprocessors, microcontrollers, embedded microcontrollers, programmable digital signal processors, programmable devices, programmable gate arrays, programmable array logic, memory devices, application specific integrated circuits, or the like. Each may be suitably employed or configured to process computer program instructions, execute computer logic, store computer data, and so on.

It will be understood that a computer may include a computer program product from a computer-readable storage medium and that this medium may be internal or external, removable and replaceable, or fixed. In addition, a computer may include a Basic Input/Output System (BIOS), firmware, an operating system, a database, or the like that may include, interface with, or support the software and hardware described herein.

Embodiments of the present invention are limited to neither conventional computer applications nor the programmable apparatus that run them. To illustrate: the embodiments of the presently claimed invention could include an optical computer, quantum computer, analog computer, or the like. A computer program may be loaded onto a computer to produce a particular machine that may perform any and all of the depicted functions. This particular machine provides a means for carrying out any and all of the depicted functions.

Any combination of one or more computer readable media may be utilized including but not limited to: a non-transitory computer readable medium for storage; an electronic, magnetic, optical, electromagnetic, infrared, or semiconductor computer readable storage medium or any suitable combination of the foregoing; a portable computer diskette; a hard disk; a random access memory (RAM); a read-only memory (ROM); an erasable programmable read-only memory (EPROM, Flash, MRAM, FeRAM, or phase change memory); an optical fiber; a portable compact disc; an optical storage device; a magnetic storage device; or any suitable combination of the foregoing. In the context of this document, a computer readable storage medium may be any tangible medium that can contain or store a program for use by or in connection with an instruction execution system, apparatus, or device.

It will be appreciated that computer program instructions may include computer executable code. A variety of languages for expressing computer program instructions may include without limitation C, C++, Java, JavaScript™, ActionScript™, assembly language, Lisp, Perl, Tcl, Python, Ruby, hardware description languages, database programming languages, functional programming languages, imperative programming languages, and so on. In embodiments, computer program instructions may be stored, compiled, or interpreted to run on a computer, a programmable data processing apparatus, a heterogeneous combination of processors or processor architectures, and so on. Without limitation, embodiments of the present invention may take the form of web-based computer software, which includes client/server software, software-as-a-service, peer-to-peer software, or the like.

In embodiments, a computer may enable execution of computer program instructions including multiple programs or threads. The multiple programs or threads may be processed approximately simultaneously to enhance utilization of the processor and to facilitate substantially simultaneous functions. By way of implementation, any and all methods, program codes, program instructions, and the like described herein may be implemented in one or more threads which may in turn spawn other threads, which may themselves have priorities associated with them. In some embodiments, a computer may process these threads based on priority or other order.

Unless explicitly stated or otherwise clear from the context, the verbs “execute” and “process” may be used interchangeably to indicate execute, process, interpret, compile, assemble, link, load, or a combination of the foregoing. Therefore, embodiments that execute or process computer program instructions, computer-executable code, or the like may act upon the instructions or code in any and all of the ways described. Further, the method steps shown are intended to include any suitable method of causing one or more parties or entities to perform the steps. The parties performing a step, or portion of a step, need not be located within a particular geographic location or country boundary. For instance, if an entity located within the United States causes a method step, or portion thereof, to be performed outside of the United States, then the method is considered to be performed in the United States by virtue of the causal entity.

While the invention has been disclosed in connection with preferred embodiments shown and described in detail, various modifications and improvements thereon will become apparent to those skilled in the art. Accordingly, the foregoing examples should not limit the spirit and scope of the present invention; rather it should be understood in the broadest sense allowable by law.

What is claimed is:

1. An apparatus for data manipulation comprising:
a plurality of random access memory (RAM) cells arranged in an array, wherein the array cells comprise bitlines and wordlines, wherein the bitlines and wordlines are functionally accessible for data storage and retrieval, wherein the functional accessibility is based on logic circuitry coupled to power inputs, address inputs, control inputs, and data inputs and outputs, and wherein the logic circuitry is further coupled to the array;
a truncation manager for controlling the bitlines within the array, wherein the truncation manager selectively controls bitline power and bitline data output;
bitline power header devices, wherein the bitline power header devices selectively distribute power along each of the bitlines; and
bitline output multiplexors, wherein the bitline output multiplexors selectively couple the bitlines to the data outputs.

2. The apparatus of claim 1 wherein the truncation manager controls a plurality of truncation logic units.

3. The apparatus of claim 2 wherein each truncation logic unit of the plurality of truncation logic units controls a bitline.

4. The apparatus of claim 2 wherein the truncation manager is controlled by one or more of the address inputs, the control inputs, and the data inputs and/or outputs.

5. The apparatus of claim 4 wherein the controlling the truncation manager enables a variable number of bitlines to be deselected.

6. The apparatus of claim 5 wherein the controlling the truncation manager further enables the deselected bitlines to be powered off using the bitline power header devices.

7. The apparatus of claim 6 wherein the controlling the truncation manager further enables deselected bitline sense amplifiers to be isolated from logic circuitry sourcing the data outputs.

8. The apparatus of claim 7 wherein the truncation manager enables flexible bit truncation within the array cells.

9. The apparatus of claim 2 wherein the bitline output multiplexors are activated based on truncation logic unit results.

10. The apparatus of claim 2 wherein the truncation logic units form a daisy chain of truncation logic units.

11. The apparatus of claim 10 wherein a first truncation logic unit of the daisy chain of truncation logic units receives a signal from the truncation manager and passes a signal on to a next truncation logic unit.

12. The apparatus of claim 11 wherein the first truncation logic unit of the daisy chain of truncation logic units controls a bitline representing the most significant bit of a data word.

13. The apparatus of claim 12 wherein a next truncation logic unit of the daisy chain of truncation logic units controls a next most significant bit of a data word.

14. The apparatus of claim 13 wherein a last truncation logic unit of the daisy chain of truncation logic units controls a bitline representing the least significant bit of a data word.

15. The apparatus of claim 10 wherein the daisy chain of truncation logic units includes a head input, a tail input, and a tail output.

16. The apparatus of claim 15 wherein the truncation manager sources each head input of each truncation logic unit.

17. The apparatus of claim 16 wherein the tail output of each truncation logic unit in the daisy chain of truncation logic units sources the head input of a next truncation logic unit in the daisy chain of truncation logic units, except the last truncation logic unit in the daisy chain of truncation logic units.

18. The apparatus of claim 1 wherein the power header devices comprise a power header device pair.

19. The apparatus of claim 18 wherein a p-type power header device of the power header device pair controls source current power distribution for the bitline.

20. The apparatus of claim 18 wherein an n-type power header device of the power header device pair controls sink current power distribution for the bitline.

21. The apparatus of claim 1 wherein the RAM cells comprise static RAM (SRAM) cells.

22. A computer program product embodied in a non-transitory computer readable medium for data manipulation, the computer program product comprising code which causes one or more processors to generate semiconductor logic for:
implementing a plurality of random access memory (RAM) cells arranged in an array, wherein the array is comprised of bitlines and wordlines, wherein the bitlines and wordlines are functionally accessible for data storage and retrieval, wherein the functional accessibility is based on logic circuitry coupled to power inputs, address inputs, control inputs, and data inputs and outputs, and wherein the logic circuitry is further coupled to the array;
implementing a truncation manager for controlling bitlines within the array, wherein the truncation manager selectively controls bitline power and bitline data output;
implementing bitline power header devices, wherein the bitline power header devices selectively distribute power along each bitline; and
implementing bitline output multiplexors, wherein the bitline output multiplexors selectively couple bitline data to the data outputs.

23. A computer system for data manipulation comprising:
a memory which stores instructions;
one or more processors coupled to the memory, wherein the one or more processors, when executing the instructions which are stored, are configured to:
access a plurality of random access memory (RAM) cells arranged in an array, wherein the array cells comprise bitlines and wordlines, wherein the bitlines and wordlines are functionally accessible for data storage and retrieval, wherein the functional accessibility is based on logic circuitry coupled to power inputs, address inputs, control inputs, and data inputs and outputs, and wherein the logic circuitry is further coupled to the array;
couple a truncation manager for controlling the bitlines within the array, wherein the truncation manager selectively controls bitline power and bitline data output;
couple bitline power header devices, wherein the bitline power header devices selectively distribute power along each of the bitlines; and
couple bitline output multiplexors, wherein the bitline output multiplexors selectively couple the bitlines to the data outputs.
